(19) United States
(12) Patent Application Publication
(10) Pub. No.: US 2018/0275207 A1
(43) Pub. Date: Sep. 27, 2018

(54) MAGNETO-OPTICAL DEFECT CENTER SENSOR WITH VIVALDI RF ANTENNA ARRAY

(71) Applicant: Lockheed Martin Corporation, Bethesda, MD (US)

(72) Inventor: Joseph W. HAHN, Erial, NJ (US)

(73) Assignee: Lockheed Martin Corporation, Bethesda, MD (US)

(21) Appl. No.: 15/468,314

(22) Filed: Mar. 24, 2017

(51) Int. Cl. G01R 33/032; G01J 1/58; H01Q 21/06; H01Q 3/24

(52) U.S. Cl. CPC G01R 33/032; H01Q 3/24; H01Q 21/064; G01J 1/58

(57) ABSTRACT

A magneto-optical defect center sensor can utilize a Vivaldi antenna array for increasing uniformity of an RF magnetic signal at a specified location of the magneto-defect center element, such as a diamond having a nitrogen vacancy.

### FIELD

The subject matter area generally relates to magnetometers, and to a magneto-optical defect sensors that include an oversampled Vivaldi antenna array for increased uniformity at a desired magneto-defect center component location.

### BACKGROUND

A number of industrial and scientific areas such as physics and chemistry can benefit from magnetic detection and imaging with a device that has extraordinary sensitivity, ability to capture signals that fluctuate very rapidly (bandwidth) all with a substantive package that is extraordinarily small in size, efficient in power and infinitesimal in volume. Many advanced magnetic imaging systems are limited to certain restrictive operating conditions, for example, high vacuum and/or cryogenic temperatures, which can make them inapplicable for applications that require ambient conditions. Furthermore, small size, weight and power (SWAP) magnetic sensors of moderate sensitivity, vector accuracy, and bandwidth can be valuable in many applications.

### SUMMARY

Some embodiments provide methods and systems for magneto-optical defect center sensors that utilize a Vivaldi antenna array for increasing uniformity of an RF magnetic signal at a specified location of the magneto-defect center element, such as a diamond having a nitrogen vacancy.

Some implementations relate to a magnetic field sensor assembly that may include an optical excitation source, a radio frequency (RF) generator, a beam former in electrical communication with the RF generator, an array of Vivaldi antenna elements in electrical communication with the beam former, and a magneto-optical defect center material positioned in a far field of the array of Vivaldi antenna elements. The array of Vivaldi antenna elements may generate a RF magnetic field that is uniform over the magneto-optical defect center material and the optical excitation source may transmit optical light at a first wavelength to the magneto-optical defect center material to detect a magnetic field based on a measurement of optical light at a second wavelength that is different from the first wavelength.

In some implementations, the array of Vivaldi antenna elements may be configured to operate in a range from 2 gigahertz (GHz) to 50 GHz. The array of Vivaldi antenna elements may include a plurality of Vivaldi antenna elements and an array lattice. The beam former may be configured to operate the array of Vivaldi antenna elements at 2 GHz or 2.8-2.9 GHz. The beam former may be configured to spatially oversample the array of Vivaldi antenna elements. The array of Vivaldi antenna elements may be adjacent the magneto-optical defect center material. The magneto-optical defect center material may be a diamond having nitrogen vacancies.

Some implementations relate to a magnetic field sensor assembly that may include a radio frequency (RF) generator, a beam former in electrical communication with the RF generator, an array of antenna elements in electrical communication with the beam former, and a magneto-optical defect center material positioned in a far field of the array of antenna elements. The array of antenna elements may generate a RF magnetic field that is uniform over the magneto-optical defect center material.

In some implementations, the array of antenna elements may be configured to operate in a range from 2 gigahertz (GHz) to 50 GHz. The array of antenna elements may include a plurality of Vivaldi antenna elements and an array lattice. The beam former may be configured to operate the array of antenna elements at 2 GHz or 2.8-2.9 GHz. The beam former may be configured to spatially oversample the array of antenna elements. The array of antenna elements may be adjacent the magneto-optical defect center material. The magneto-optical defect center material may be a diamond having nitrogen vacancies.

Other implementations relate to a magnetic field sensor assembly that may include a radio frequency (RF) generator, an array of antenna elements in electrical communication with the RF generator, and a magneto-optical defect center material positioned in a far field of the array of antenna elements. The array of antenna elements may generate a RF magnetic field that is uniform over the magneto-optical defect center material.

In some implementations, the array of antenna elements may be configured to operate in a range from 2 gigahertz (GHz) to 50 GHz. The magnetic field sensor assembly may include a beam former configured to operate the array of antenna elements at 2.8-2.9 GHz. The array of antenna elements may include a plurality of Vivaldi antenna elements and an array lattice.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 illustrates an orientation of an NV center in a diamond lattice;

FIG. 2 illustrates an energy level diagram showing energy levels of spin states for the NV center;

FIG. 3 illustrates a schematic diagram of a NV center magnetic sensor system;

FIG. 4 is a graph illustrating the fluorescence as a function of an applied RF frequency of an NV center along a given direction for a zero magnetic field, and also for a non-zero magnetic field having a component along the NV axis;

FIG. 5 is a graph illustrating the fluorescence as a function of an applied RF frequency for four different NV center orientations for a non-zero magnetic field;

FIG. 6 is a schematic illustrating an NV center magnetic sensor system in accordance with some illustrative implementations;

FIG. 7 is a graphical diagram depicting a Ramsey pulse sequence;

FIG. 8. is a schematic illustrating some implementations of a Vivaldi antenna;

FIG. 9 is a schematic illustrating some implementations of an array of Vivaldi antennae; and

FIG. 10 is a block diagram of some RF systems for the magneto-defect center sensor.

It will be recognized that some or all of the figures are schematic representations for purposes of illustration. The figures are provided for the purpose of illustrating embodiments with the explicit understanding that they will not be used to limit the scope or the meaning of the claims.

### DETAILED DESCRIPTION

Atomic-sized magneto-optical defect centers, such as nitrogen-vacancy (NV) centers in diamond lattices, can have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Diamond nitrogen vacancy (DNV) sensors may be maintained in room temperature and atmospheric pressure and can be even used in liquid environments. A green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with ms=−1, 0, +1) of the NV centers to split based upon an external magnetic field projected along the NV axis, resulting in two spin resonance frequencies. The distance between the two spin resonance frequencies is a measure of the strength of the external magnetic field. A photo detector can measure the fluorescence (red light) emitted by the optically excited NV centers.

Magneto-optical defect center materials are those that can modify an optical wavelength of light directed at the defect center based on a magnetic field in which the magneto-defect center material is exposed. In some implementations, the magneto-defect center material may utilize nitrogen vacancy centers. Nitrogen-vacancy (NV) centers are defects in a diamond's crystal structure. Synthetic diamonds can be created that have these NV centers. NV centers generate red light when excited by a light source, such as a green light source, and microwave radiation. When an excited NV center diamond is exposed to an external magnetic field, the frequency of the microwave radiation at which the diamond generates red light and the intensity of the light change. By measuring this change and comparing the change to the microwave frequency that the diamond generates red light at when not in the presence of the external magnetic field, the external magnetic field strength can be determined. Accordingly, NV centers can be used as part of a magnetic field sensor.

In some implementations, microwave RF excitation is needed in a DNV sensor. The more uniform the microwave signal is across the NV centers in the diamond, the better and more accurate an NV sensor can perform. Uniformity, however, can be difficult to achieve. Also, the larger the bandwidth of the element, the better the NV sensor can perform. Large bandwidth, such as octave bandwidth, however, can be difficult to achieve. Various NV sensors respond to a microwave frequency that is not easily generated by RF antenna elements that are comparable to the small size of the NV sensor. In addition, RF elements reduce the amount of light within the sensor that is blocked by the RF elements. When a single RF element is used, the RF element is offset from the NV diamond when the RF element maximized the faces and edges of the diamond that light can enter or leave. Moving the RF element away from the NV diamond, however, impacts the uniformity of strength of the RF that is applied to the NV diamond.

Some of the embodiments realize that the DNV magnetic sensors with dual RF elements provide a number of advantages. As described in greater detail below, using a two RF element arrangement in a DNV sensor can allow greater access to the edges and faces of the diamond for light input and egress, while still exciting the NV centers with a uniform RF field. In some implementations, each of the two microwave RF elements is contained on a circuit board. The RF elements can include multiple stacked spiral antenna coils. These stacked coils can occupy a small footprint and can provide the needed microwave RF field in such that the RF field is uniform over the NV diamond.

In addition, all edges and faces of the diamond can be used for light input and egress. The more light captured by photo-sensing elements of a DNV sensor results in an increased efficiency of the sensor. Various implementations use the dual RF elements to increase the amount of light collected by the DNV sensor. The dual RF elements can be fed by a single RF feed or by two separate RF feeds. If there are two RF feeds, the feeds can be individual controlled creating a mini-phased array antenna effect, which be enhance the operation of the DNV sensor.

NV Center, its Electronic Structure, and Optical and RF Interaction

The nitrogen vacancy (NV) center in diamond comprises a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. Conventionally, the neutral charge state uses the nomenclature NV⁰, while the negative charge state uses the nomenclature NV, which is adopted in this description.

The NV center has a number of electrons including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

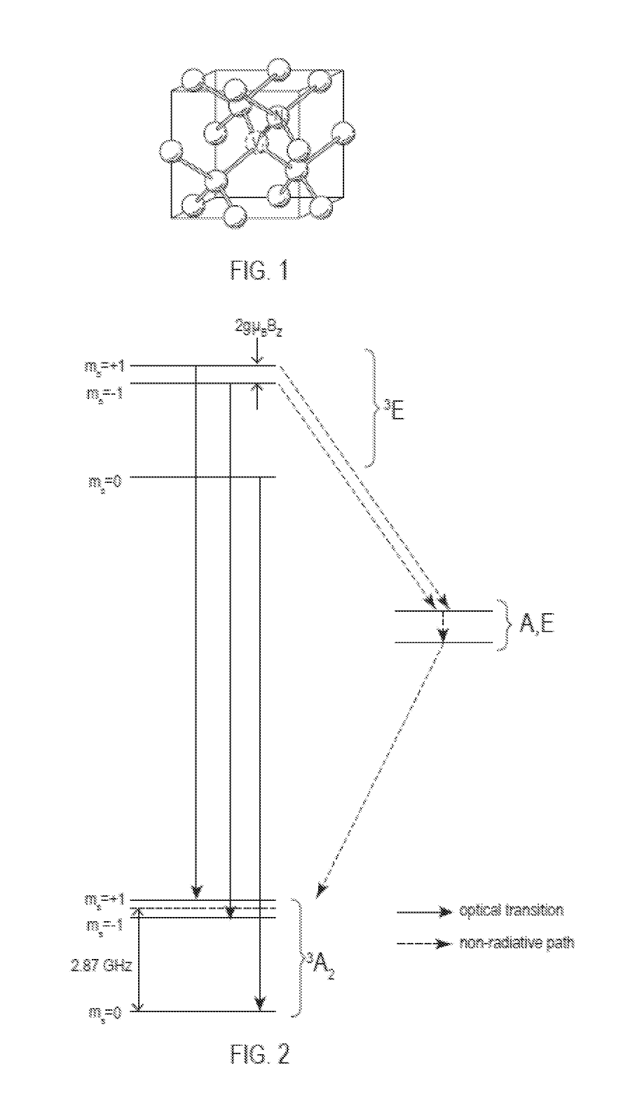

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels mₛ=±1 by an amount 2gμ_{B}Bz, where g is the g-factor, μ_{B} is the Bohr magneton, and Bz is the component of the external magnetic field along the NV axis. This relationship is correct for a first order and inclusion of higher order corrections is a straight forward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states which have the same spin. For a direct transition between the excited triplet ³E and the ground state ³A₂, a photon of red light is emitted with a photon energy corresponding to the energy difference between the energy levels of the transitions.

There is, however, an alternate non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A_{z} predominantly decays to the mₛ=0 spin state over the mₛ=±1 spin states. These features of the decay from the excited triplet ³E state via the intermediate singlet states A, E to the ground state triplet ³A allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

NV Center, or Magneto-Optical Defect Center, Magnetic Sensor System

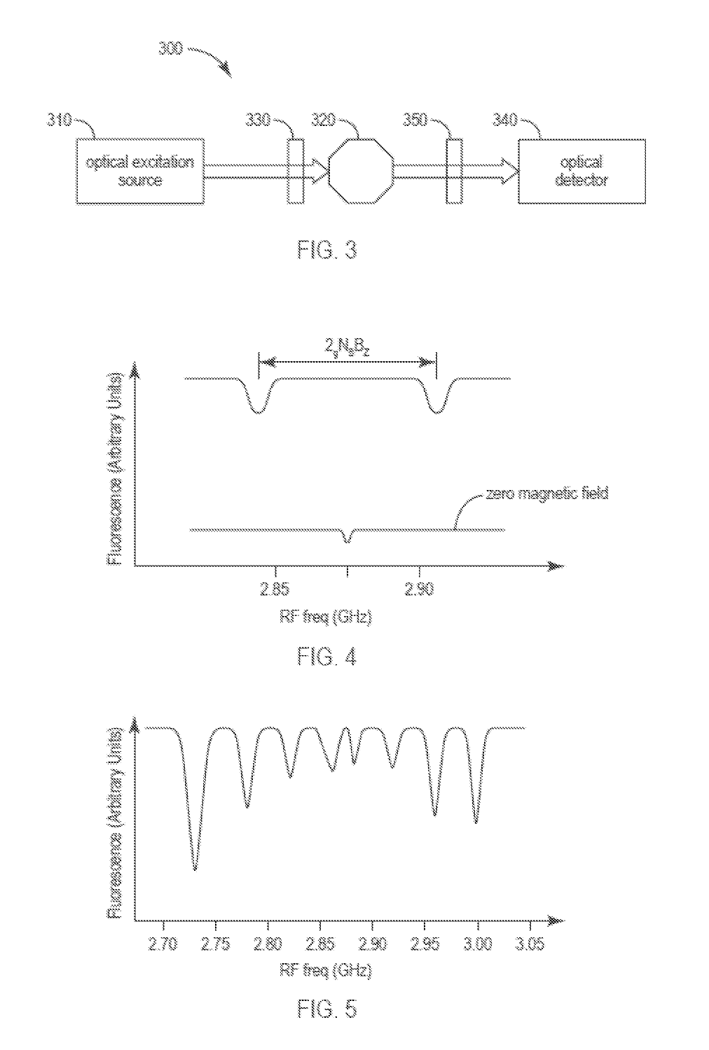

FIG. 3 is a schematic illustrating a NV center magnetic sensor system 300 which uses fluorescence intensity to distinguish the mₛ=±1 states, and to measure the magnetic field based on the energy difference between the mₛ=+1 state and the mₛ=−1 state. The system 300 includes an optical excitation source 310, which directs optical excitation to an NV diamond material 320 with NV centers. The system 300 further includes an RF excitation source 330 which provides RF radiation to the NV diamond material 320. Light from the NV diamond may be directed through an optical filter 350 to an optical detector 340.

The RF excitation source 330 may be a microwave coil, for example. The RF excitation source 330 when emitting RF radiation with a photon energy resonant with the transition energy between ground mₛ=0 spin state and the mₛ=+1 spin state excites a transition between those spin states. For such a resonance, the spin state cycles between ground mₛ=0 spin state and the mₛ=+1 spin state, reducing the population in the mₛ=0 spin state and reducing the overall fluorescence at resonance. Similarly resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state. At resonance between the mₛ=0 spin state and the mₛ=−1 spin state, or between the mₛ=0 spin state and the mₛ=+1 spin state, there is a decrease in the fluorescence intensity.

The optical excitation source 310 may be a laser or a light emitting diode, for example, which emits light in the green, for example. The optical excitation source 310 induces fluorescence in the red, which corresponds to an electronic transition from the excited state to the ground state. Light from the NV diamond material 320 is directed through the optical filter 350 to filter out light in the excitation band (in the green for example), and to pass light in the red fluorescence band, which in turn is detected by the detector 340. The optical excitation light source 310, in addition to exciting fluorescence in the diamond material 320, also serves to reset the population of the mₛ=0 spin state of the ground state ³A₂ to a maximum polarization, or other desired polarization.

For continuous wave excitation, the optical excitation source 310 continuously pumps the NV centers, and the RF excitation source 330 sweeps across a frequency range which includes the zero splitting (when the mₛ=±1 spin states have the same energy) photon energy of 2.87 GHz. The fluorescence for an RF sweep corresponding to a diamond material 320 with NV centers aligned along a single direction is shown in FIG. 4 for different magnetic field components Bz along the NV axis, where the energy splitting between the mₛ=−1 spin state and the mₛ=+1 spin state increases with Bz. Thus, the component Bz may be determined. Optical excitation schemes other than continuous wave excitation are contemplated, such as excitation schemes involving pulsed optical excitation, and pulsed RF excitation. Examples, of pulsed excitation schemes include Ramsey pulse sequence and spin echo pulse sequence.

In general, the diamond material 320 will have NV centers aligned along directions of four different orientation classes. FIG. 5 illustrates fluorescence as a function of RF frequency for the case where the diamond material 320 has NV centers aligned along directions of four different orientation classes. In this case, the component Bz along each of the different orientations may be determined. These results along with the known orientation of crystallographic planes of a diamond lattice allows not only the magnitude of the external magnetic field to be determined, but also the direction of the magnetic field.

While FIG. 3 illustrates an NV center magnetic sensor system 300 with NV diamond material 320 with a plurality of NV centers, in general the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

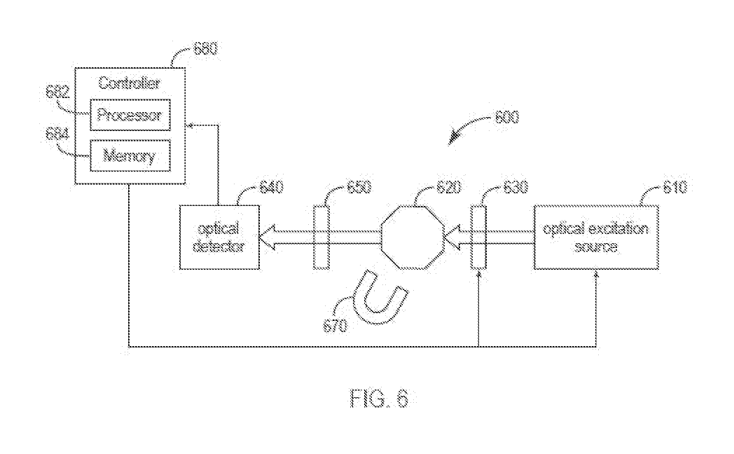

FIG. 6 is a schematic of an NV center magnetic sensor 600, according to an embodiment. The sensor 600 includes an optical excitation source 610, which directs optical excitation to an NV diamond material 620 with NV centers, or another magneto-optical defect center material with magneto-optical defect centers. An RF excitation source 630 provides RF radiation to the NV diamond material 620. The NV center magnetic sensor 600 may include a bias magnet 670 applying a bias magnetic field to the NV diamond material 620. Light from the NV diamond material 620 may be directed through an optical filter 650 and an electromagnetic interference (EMI) filter 660, which suppresses conducted interference, to an optical detector 640. The sensor 600 further includes a controller 680 arranged to receive a light detection signal from the optical detector 640 and to control the optical excitation source 610 and the RF excitation source 630.

The RF excitation source 630 may be a microwave coil, for example. The RF excitation source 630 is controlled to emit RF radiation with a photon energy resonant with the transition energy between the ground mₛ=0 spin state and the mₛ=±1 spin states as discussed above with respect to FIG. 3.

The optical excitation source 610 may be a laser or a light emitting diode, for example, which emits light in the green, for example. The optical excitation source 610 induces fluorescence in the red, which corresponds to an electronic transition from the excited state to the ground state. Light from the NV diamond material 620 is directed through the optical filter 650 to filter out light in the excitation band (in the green for example), and to pass light in the red fluorescence band, which in turn is detected by the optical detector 640. The EMI filter 660 is arranged between the optical filter 650 and the optical detector 640 and suppresses conducted interference. The optical excitation light source 610, in addition to exciting fluorescence in the NV diamond material 620, also serves to reset the population of the mₛ=0 spin state of the ground state ³A₂ to a maximum polarization, or other desired polarization.

The controller 680 is arranged to receive a light detection signal from the optical detector 640 and to control the optical excitation source 610 and the RF excitation source 630. The controller may include a processor 682 and a memory 684, in order to control the operation of the optical excitation source 610 and the RF excitation source 630. The memory 684, which may include a nontransitory computer readable medium, may store instructions to allow the operation of the optical excitation source 610 and the RF excitation source 630 to be controlled.

According to one embodiment of operation, the controller 680 controls the operation such that the optical excitation source 610 continuously pumps the NV centers of the NV diamond material 620. The RF excitation source 630 is controlled to continuously sweep across a frequency range which includes the zero splitting (when the mₛ=±1 spin states have the same energy) photon energy of 2.87 GHz. When the photon energy of the RF radiation emitted by the RF excitation source 630 is the difference in energies of the mₛ=0 spin state and the mₛ=−1 or mₛ=+1 spin state, the overall fluorescence intensity is reduced at resonance, as discussed above with respect to FIG. 3. In this case, there is a decrease in the fluorescence intensity when the RF energy resonates with an energy difference of the mₛ=0 spin state and the mₛ=−1 or mₛ=+1 spin states. In this way the component of the magnetic field Bz along the NV axis may be determined by the difference in energies between the mₛ=−1 and the mₛ=+1 spin states.

As noted above, the diamond material 620 will have NV centers aligned along directions of four different orientation classes, and the component Bz along each of the different orientations may be determined based on the difference in energy between the mₛ=−1 and the mₛ=+1 spin states for the respective orientation classes. In certain cases, however, it may be difficult to determine which energy splitting corresponds to which orientation class, due to overlap of the energies, etc. The bias magnet 670 provides a magnetic field, which is preferably uniform on the NV diamond material 620, to separate the energies for the different orientation classes, so that they may be more easily identified.

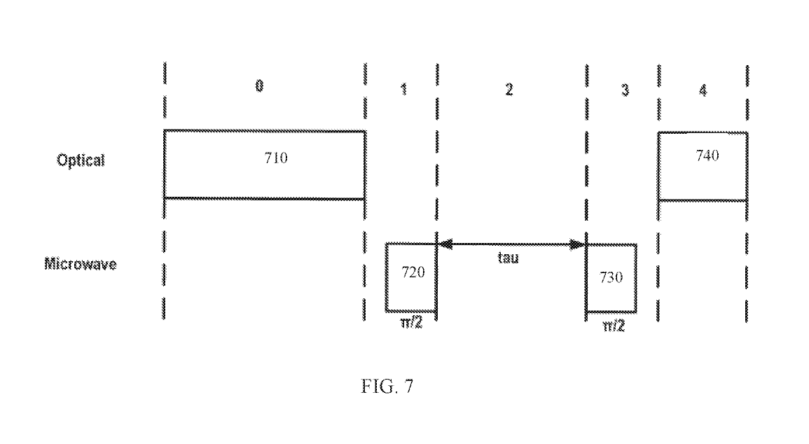

A Ramsey pulse sequence is a pulsed RF-pulsed laser scheme that measures the free precession of the magnetic moment in the diamond material 320, 620 with NV centers, and is a technique that quantum mechanically prepares and samples the electron spin state. FIG. 7 is a schematic diagram illustrating the Ramsey pulse sequence. As shown in FIG. 7, a Ramsey pulse sequence includes optical excitation pulses and RF excitation pulses over a five-step period. In a first step, during a period 0, a first optical excitation pulse 710 is applied to the system to optically pump electrons into the ground state (i.e., mₛ=0 spin state). This is followed by a first RF excitation pulse 720 (in the form of, for example, a microwave (MW) π/2 pulse) during a period 1. The first RF excitation pulse 720 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 730 (in the form of, for example, a MW π/2 pulse) is applied during a period 3 to project the system back to the mₛ=0 and mₛ=+1 basis. Finally, during a period 4, a second optical pulse 740 is applied to optically sample the system and a measurement basis is obtained by detecting the fluorescence intensity of the system. The RF excitation pulses applied are provided at a given RF frequency, which correspond to a given NV center orientation.

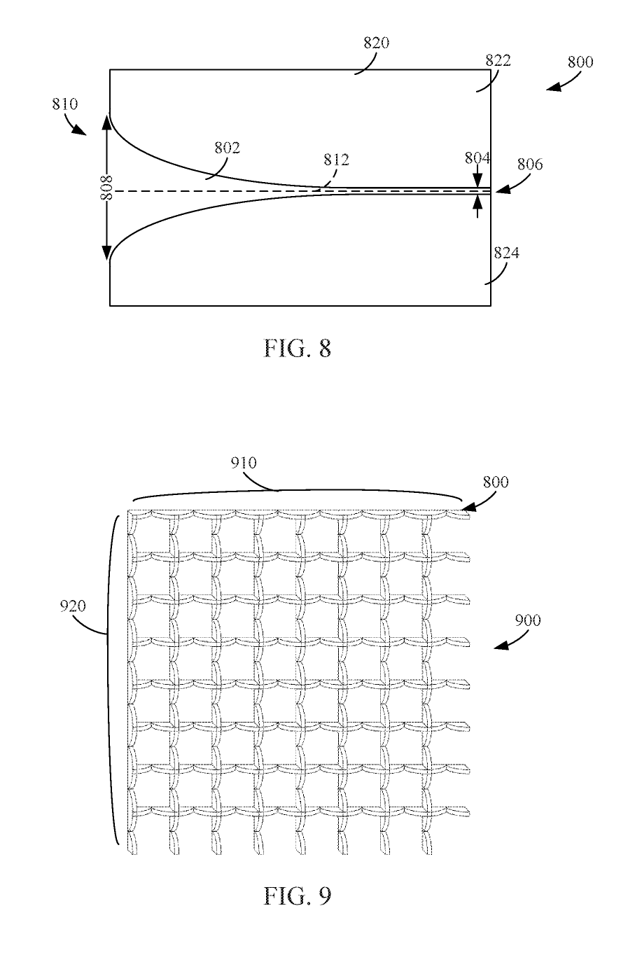

FIG. 8 depicts an implementation of a Vivaldi or tapered slot antenna element 800. In the implementation shown, a conductive layer 820 is positioned on a substrate for the Vivaldi antenna element 800. A slot 802 is formed in the conductive layer 820 that widens from a minimum distance 804 at a first end 806 of the slot 802 to a maximum distance 808 at a second end 810. The opening of the slot 802 is symmetrical in the implementation shown about an axis 812 along the length of the slot 802 and each side 822, 824 of the conductive layer 820 widens outwardly as the slot 802 approaches the second end 810.

The Vivaldi antenna element 800 can be constructed from a pair of symmetrical conductive layers 820 on opposing sides of a thin substrate layer. The conductive layers 820 are preferably substantially identical with the slot 802 formed in each conductive layer 820 pair being parallel. The Vivaldi antenna element 800 is fed by a transmission line (not shown) at the first end 806 and radiates from the second end 810. The size, shape, configuration, and/or positioning of the transmission line of the Vivaldi antenna element 800 may be modified for different bandwidths for the Vivaldi antenna element 800.

As shown in FIG. 9, a plurality of Vivaldi antenna elements 800 may be arranged in an array 900. The array 900 may include Vivaldi antenna elements 800 in a two-dimensional configuration with Vivaldi antenna elements 800 arranged horizontally 910 and vertically 920 in a plane 802 of the array 900. In some implementations, the Vivaldi antenna elements 800 may be uniform in size and configuration. In other implementations, the Vivaldi antenna elements 800 may have different sizes and/or configurations based on a position of the corresponding Vivaldi antenna element 800 in the array 900 and/or based on a target far-field uniformity for a magneto-optical defect center element positioned relative to the array 900. In some implementations, the array 900 of Vivaldi antenna elements 800 is configured to be oversampled to operate over a frequency band centered at 2.87 GHz. Each individual Vivaldi antenna element 800 may be designed to operate from approximately 2 GHz to 40 GHz. The array 900 may include 64 to 196 individual Vivaldi antenna elements 800.

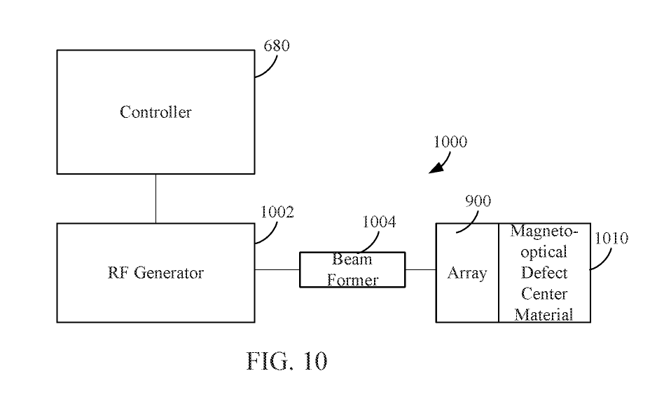

FIG. 10 depicts an RF system 1000 for a magneto-optical defect center sensor, such as the NV center magnetic sensor 600 of FIG. 6. A magneto-optical defect center sensor may use an RF excitation method that has substantial uniformity over a portion of the magneto-optical defect center material 1010 that is illuminated by the optical excitation source, such as the optical excitation source 610 of FIG. 6. A spatially oversampled Vivaldi antenna array, such as the array 900 of FIG. 9, can be implemented to achieve a high uniformity in a compact size through the use of small Vivaldi antenna elements 800 to permit the magneto-optical defect center material 1010 to effectively be in the far field of the array, thereby decreasing the distance needed between the magneto-optical defect center material 1010 and the array 900.

As shown in FIG. 10, the RF system includes an RF generator 1002, a beam former system 1004, and the Vivaldi antenna element array 900. The RF generator 1002 is configured to generate an RF signal for generating an RF magnetic field for the magneto-optical defect center sensor based on an output from the controller 680. Each Vivaldi antenna element 800 of the array 900 can be designed to work from 2 gigahertz (GHz) to 40 GHz. In some implementations, each Vivaldi antenna element 800 of the array 900 can be designed to work at other frequencies, such as 50 GHz. The Vivaldi antenna elements 800 are positioned on an array lattice or other substructure correlating to 40 GHz. In some implementations, the array lattice may be a small size, such as 0.1 inches by 0.1 inches. Each Vivaldi antenna element 800 of the array 900 is electrically coupled to the beam former system 1004. The combination of the Vivaldi antenna elements 800 permits the array 900 to operate at lower frequencies than each Vivaldi antenna element 800 making up the array 900.

The beam former system 1004 is configured to spatially oversample the Vivaldi antenna elements 800 of the array 900 such that the array 900 of Vivaldi antenna elements 800 effectively operates like a single element at 2 GHz. The beam former system 1004 may include a circuit of several Wilkinson power splitters. In some implementations, the beam former system 1004 may be configured to spatially oversample the Vivaldi antenna elements 800 of the array 900 such that the array 900 of Vivaldi antenna elements 800 perform like a single element at other frequencies, such as 2.8-2.9 GHz. A single 2 GHz antenna would typically require an increased distance for the magneto-optical defect center material 1010 to be located in the far field. If the magneto-optical defect center material 1010 is moved into the near field, decreased uniformity occurs. However, since the array 900 is composed of much smaller Vivaldi antenna elements 800, the far field of each element 800 is much closer than a single 2 GHz antenna. Thus, the magneto-optical defect center material 1010 is able to be positioned much closer to still be in the far field of the array 900. Due to oversampling provided by the beam former system 1004 of the array 900 of very small Vivaldi antenna elements 800 the magneto-optical defect center material 1010 is able to be positioned in the far field of the array 900 and achieve a high uniformity.

Because of the high uniformity for the RF magnetic field provided by the array 900, the magneto-optical defect center material 1010 can be at multiple different orientations, thereby providing additional adaptability for designing the magneto-optical defect center sensor. That is, the magneto-optical defect center material 1010 may be mounted to a light pipe for collected red wavelength light emitted from the magneto-optical defect center material 1010 when excited by a green wavelength optical excitation source, and the array 900 can be maneuvered to a number of different positions to accommodate any preferred configurations for the positioning of the light pipe and/or optical excitation source. By providing the array 900 of Vivaldi antenna elements 800, the magneto-optical defect center sensor can have a more customized and smaller configuration compared to other magneto-optical defect center sensors.

In addition, in some implementations, the array 900 may be able to control the directionality of the generated RF magnetic field. That is, because of the several Vivaldi antenna elements 800 making up the array 900, the directionality of the resulting RF magnetic field can be modified based on which of the Vivaldi antenna elements 800 are active and/or the magnitude of the transmission from each of the Vivaldi antenna elements 800. In some implementations, one or more phase shifters may be positioned between a corresponding output of a beam former of the beam former system 1004 for a Vivaldi antenna element 800. The one or more phase shifters may be selectively activated or deactivated to provide constructive or destructive interference so as to “steer” each RF magnetic field generated from each Vivaldi antenna element 800 in a desired direction. Thus, in some implementations it may be possible to “steer” the generated RF magnetic field to one or more lattices of the magneto-optical defect center material 1010.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology. In some aspects, the subject technology may be used in various markets, including for example and without limitation, advanced sensors and mobile space platforms.

There may be many other ways to implement the subject technology. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made to the subject technology, by one having ordinary skill in the art, without departing from the scope of the subject technology.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A magnetic field sensor assembly comprising:
an optical excitation source;
a radio frequency (RF) generator;
a beam former in electrical communication with the RF generator;
an array of Vivaldi antenna elements in electrical communication with the beam former; and
a magneto-optical defect center material positioned in a far field of the array of Vivaldi antenna elements, wherein the array of Vivaldi antenna elements generate a RF magnetic field that is uniform over the magneto-optical defect center material, wherein the optical excitation source transmits optical light at a first wavelength to the magneto-optical defect center material to detect a magnetic field based on a measurement of optical light at a second wavelength that is different from the first wavelength.

2. The magnetic field sensor assembly of claim 1, wherein the array of Vivaldi antenna elements is configured to operate in a range from 2 gigahertz (GHz) to 50 GHz.

3. The magnetic field sensor assembly of claim 1, wherein the array of Vivaldi antenna elements comprises a plurality of Vivaldi antenna elements and an array lattice.

4. The magnetic field sensor assembly of claim 1, wherein the beam former is configured to operate the array of Vivaldi antenna elements at 2 GHz.

5. The magnetic field sensor assembly of claim 1, wherein the beam former is configured to operate the array of Vivaldi antenna elements at 2.8-2.9 GHz.

6. The magnetic field sensor assembly of claim 1, wherein the beam former is configured to spatially oversample the array of Vivaldi antenna elements.

7. The magnetic field sensor assembly of claim 1, wherein the array of Vivaldi antenna elements is adjacent the magneto-optical defect center material.

8. The magnetic field sensor assembly of claim 1, wherein the magneto-optical defect center material is a diamond having nitrogen vacancies.

9. A magnetic field sensor assembly comprising:
a radio frequency (RF) generator;
a beam former in electrical communication with the RF generator;
an array of antenna elements in electrical communication with the beam former; and
a magneto-optical defect center material positioned in a far field of the array of antenna elements, wherein the array of antenna elements generate a RF magnetic field that is uniform over the magneto-optical defect center material.

10. The magnetic field sensor assembly of claim 8, wherein the array of antenna elements is configured to operate in a range from 2 gigahertz (GHz) to 50 GHz.

11. The magnetic field sensor assembly of claim 8, wherein the array of antenna elements comprises a plurality of Vivaldi antenna elements and an array lattice.

12. The magnetic field sensor assembly of claim 8, wherein the beam former is configured to operate the array of antenna elements at 2 GHz.

13. The magnetic field sensor assembly of claim 8, wherein the beam former is configured to operate the array of antenna elements at 2.8-2.9 GHz.

14. The magnetic field sensor assembly of claim 8, wherein the beam former is configured to spatially oversample the array of antenna elements.

15. The magnetic field sensor assembly of claim 8, wherein the array of antenna elements is adjacent the magneto-optical defect center material.

16. The magnetic field sensor assembly of claim 8, wherein the magneto-optical defect center material is a diamond having nitrogen vacancies.

17. A magnetic field sensor assembly comprising:
a radio frequency (RF) generator;
an array of antenna elements in electrical communication with the RF generator; and
a magneto-optical defect center material positioned in a far field of the array of antenna elements, wherein the array of antenna elements generate a RF magnetic field that is uniform over the magneto-optical defect center material.

18. The magnetic field sensor assembly of claim 17, wherein the array of antenna elements is configured to operate in a range from 2 gigahertz (GHz) to 50 GHz.

19. The magnetic field sensor assembly of claim 18 further comprising a beam former configured to operate the array of antenna elements at 2.8-2.9 GHz.

20. The magnetic field sensor assembly of claim 19, wherein the array of antenna elements comprises a plurality of Vivaldi antenna elements and an array lattice.
